(19) United States
(12) Patent Application Publication
(10) Pub. No.: US 2005/0148173 A1
(43) Pub. Date: Jul. 7, 2005

(54) Non-volatile memory array having vertical transistors and manufacturing method thereof

(76) Inventor: Fuja Shone, Hsinchu (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/750,893

(22) Filed: Jan. 5, 2004

(51) Int. Cl. H01L 21/44

(52) U.S. Cl. 438/672

(57) ABSTRACT

A method of manufacturing a non-volatile memory array having vertical field effect transistors is revealed. First, a semiconductor substrate having multiple trenches is provided, and then dopants are implanted into the semiconductor substrate to form first doping regions and second doping regions respectively serving as source and drain bit lines at different heights. Secondly, a gate dielectric including at least one nitride film, e.g., an oxide/nitride/oxide (ONO) layer, is formed onto the surface of the semiconductor substrate, and polysilicon plugs serving as gate electrodes are filled up the multiple trenches afterward. After that, a polysilicon layer and a tungsten silicide (WiSix) layer are sequentially deposited followed by masking and etching processes to form parallel polycide lines serving as word lines, and then an oxide layer is deposited therebetween and planarized for isolation.

### BACKGROUND OF THE INVENTION

(A) Field of the Invention

The present invention is related to a non-volatile memory array and manufacturing method thereof, and more particularly to a non-volatile memory array having vertical transistors, or namely vertical memory cells, and manufacturing method thereof.

(B) Description of the Related Art

During late 1980s, a non-volatile erasable programmable read only memory (EPROM), which had the advantages of low cost and high density, was developed. An EPROM can only proceed programming operations, however, a flash memory developed thereafter can proceed with erasing in addition to programming. The flash memory uses a positive potential on a gate and a drain to make the hot electrons enter the floating gate for programming. Moreover, the source side erase using the Fowler-Nordheim (F-N) tunneling effect expels the electrons from the gate into a source for the erasing operation.

With the development of a high degree integration on a substrate, scaling down the above mentioned non-volatile memory cell is rather hindered due to inherent dimensions of source, and drain and gate channel thereof, so the roadmap of high volume non-volatile memory may slow down significantly. Accordingly, development of small memory cell is crucial for the next generation, and thus vertical transistors have been attracting a lot of attention recently.

U.S. Pat. Nos. 5,739,567, 5,770,514, 6,544,824 and 6,365,452 disclose numerous non-volatile vertical memory cells, they employ vertical floating gates basically. For instance, FIG. 1(a) shows cross-sectional view of a vertical stacked gate EEPROM transistor 500 of U.S. Pat. No. 5,739,567, wherein a channel region 503 is formed on top of a source region 502, and drain regions 504 are formed on top of the channel region 503. Floating gates 505 are formed on the sidewalls 506 of a trench 507. A gate dielectric film 508 is formed between floating gate 505 and source region 502, drain region 504, as well as channel region 503. A control gate 509 formed adjacent to the floating gate 505 in trench 507, covers the floating gate 505. The control gate 509 is insulated from the floating gate 505 and the source region 502 by a layer of dielectric film 510. The cell 500 is programmed by conventional hot electron injection and is flash erased by electron tunneling from the floating gate 505 to either the source region 502 or the drain region 504. The drain regions 504 and source regions 502 are at different heights, and the gate dielectric films 508 are located vertically. Obviously, the gate channels do not occupy any space in horizontal, so a high degree integration can be attained. However, owing to the lateral thickness of the floating gate 505, the extent of scaling down is rather limited.

FIGS. 1(b) through 1(d) show a process for manufacturing a vertical transistor in accordance with U.S. Pat. No. 5,770,514. As illustrated in FIG. 1(b), a double diffusion layer, including a p-type base diffusion layer 131 and an n⁺-type source diffusion layer 141, is formed in a surface region of an n⁻-type epitaxial layer 121 on an n⁺-type semiconductor substrate 111.

A trench 151 is then formed by anisotropic etching such as RIE, using a CVD film (not shown) as a mask. The trench 151 reaches the epitaxial layer 121 through the source and base diffusion layers 141 and 131. After that, a gate oxide film 161 is formed on the trench 151, and a polysilicon layer 171 is deposited thereon by low pressure CVD or the like, with the result that the trench 151 is filled with the polysilicon layer 171. The layer 171 is previously doped with n-type impurities such as phosphorus to be conductive. Subsequently, as shown in FIG. 1(c), the polysilicon layer 171 is etched back by CDE (Chemical Dry Etching) or the like to the same level as the surface of the source diffusion layer 141, that is, the layer 171 is to substantially the same level as the entrance of the trench 151. As shown in FIG. 1(d), a polysilicon layer 181 doped with n-type impurities beforehand is selectively grown on the polysilicon layer 171 buried in the trench 151 by, e.g., epitaxial growth. The layer 181 protrudes from the trench 151 and it is narrower than the width of the trench 151. The polysilicon layers 171 and 181 thus constitute a trench gate 151A which does not cover the upper corner portions of the trench 151. With this constitution, no electrodes are formed at the corner portions 271, and the concentration of electric field can be mitigated at the corner portions. Since, therefore, the gate oxide film 161 can be protected from a breakdown, the insulation properties of the gate oxide film 161 can be improved at the corner portions 271, and a sufficiently high absolute withstanding voltage can easily be maintained. However, because the impurities have to be formed in the substrate before trench formation, the process convenience and flexibility are diminished tremendously.

Recently, IEDM (International Electronic Device Meeting) Conference on December 2003 reveals silicon nanocrystal (Si-nc) memories, a fully CMOS compatible technology based on discrete storage nodes, which has serious potential for pushing further the scaling limits of conventional non-volatile memories. As shown in FIG. 1(e), a layer 102 comprising silicon nanocrystal particles is formed between a gate 103 and a silicon substrate 101 including two n-type regions 104 as a gate dielectric. Despite the nanocrystal memories provide an alternative way for non-volatile memories, the extent of scaling down is still somewhat limited.

### SUMMARY OF THE INVENTIION

The objective of the present invention is to provide a non-volatile memory array having vertical transistors and manufacturing method thereof, in case of a non-floating-gate type, to meet the scaling criteria for the next generation, introducing the formation of a gate dielectric having at least one nitride film, virtual ground drain/source bit lines, a common source, etc., to acquire superior charge storing and reduce the number of contacts to the memory array.

To achieve the above objective, a non-volatile memory array having vertical transistors has been developed for improving a high degree of integration. At least one of the vertical transistors is formed in a trench of a semiconductor substrate and comprises a first doping region, a second doping region, a gate dielectric layer and a conducting plug, where the first and second doping regions are of first conductive type, i.e., N type, and are underneath the bottom of the trench and beside the top of the trench, respectively. The gate dielectric layer including at least one nitride film formed on the first doping region, the second doping region and the sidewall of the trench. The conducting plug, e.g., a polysilicon plug, is formed in the trench.

Furthermore, the first doping regions of the vertical transistors can be connected as a common source or a common drain, so as to decrease the number of contacts to the sources or drains and to isolate vertical transistor's operation from the substrate.

The method for making the above non-volatile memory array having vertical transistors is described as follows. First, a semiconductor substrate having multiple trenches is provided, and then dopants are implanted into the semiconductor substrate to form first doping regions and second doping regions respectively serving as source and drain bit lines at different heights, wherein the first regions are underneath the bottom of the trenches, and the second regions are beside the top of the trenches. Secondly, a gate dielectric having at least one nitride film such as an oxide/nitride/oxide (ONO) layer or the like is deposited onto the surface of the semiconductor substrate, and conducting plugs, e.g., polysilicon plugs, serving as gate electrodes are filled up the multiple trenches afterward. Up to now, the bit lines (source/drain) and gate electrodes have been constructed. After planarization of the conducting plugs on the substrate, a polysilicon layer, a tungsten silicide (WiSix) layer and an etch stop layer, e.g., a silicon nitride layer, are sequentially deposited, followed by lithography and etching processes to form parallel polycide lines serving as word lines and holes separating the polysilicon plugs. Then, an oxide layer is deposited to fill up the holes and the gaps between polycide lines for isolation, and a planarization of the oxide layer may be carried out to have a planar surface.

Moreover, a thermal process may be further employed to diffuse the dopants within the first doping regions to connect the first doping regions as a common source or a common drain.

### BRIEF DESCRIPTION OF THE DRAWINGS

FIG. 1(a) illustrates a known EEPROM of vertical transistors;

FIGS. 1(b) through 1(d) illustrate a known process for manufacturing a vertical transistor;

FIG. 1(e) illustrates a known silicon nanocrystal memory cell;

FIGS. 2 through 10 illustrate a method for manufacturing a non-volatile memory having vertical transistors in accordance with the present invention;

FIG. 11 illustrates an optional step which may be added to the method for manufacturing non-volatile memory having vertical transistors in accordance with the present invention;

FIG. 12 illustrates an alternative method for manufacturing non-volatile memory having vertical transistors in accordance with the present invention;

FIG. 13 illustrates another optional step which may be added to the method for manufacturing non-volatile memory having vertical transistors in accordance with the present invention;

FIGS. 14 and 15 illustrate an alternative process to form the first and second doping regions in accordance with the present invention; and

FIGS. 16 and 17 illustrate another alternative process to form the first and second doping regions in accordance with the present invention; and

FIG. 18 illustrates non-volatile memory cells using silicon nanocrystals in accordance with the present invention.

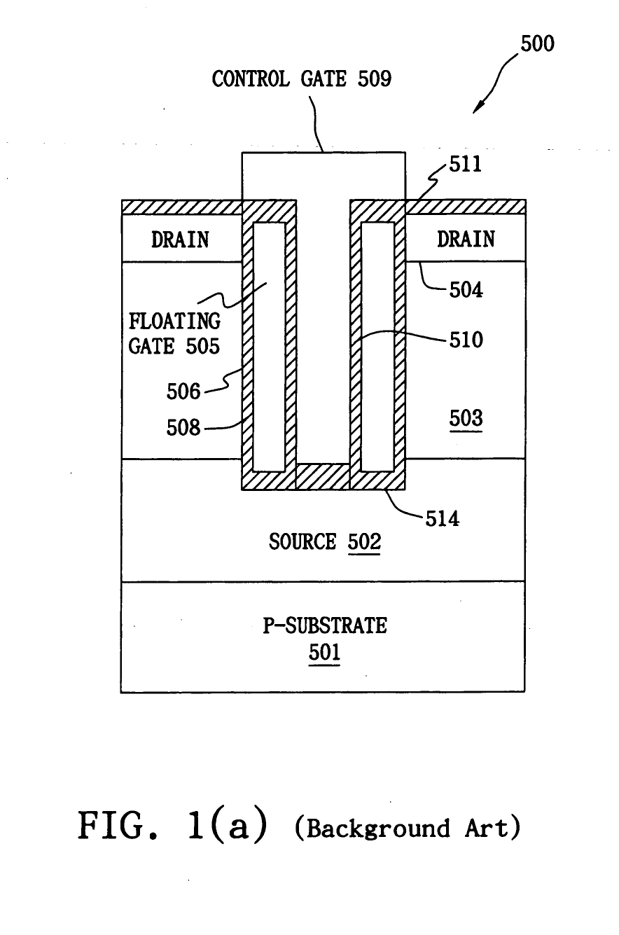

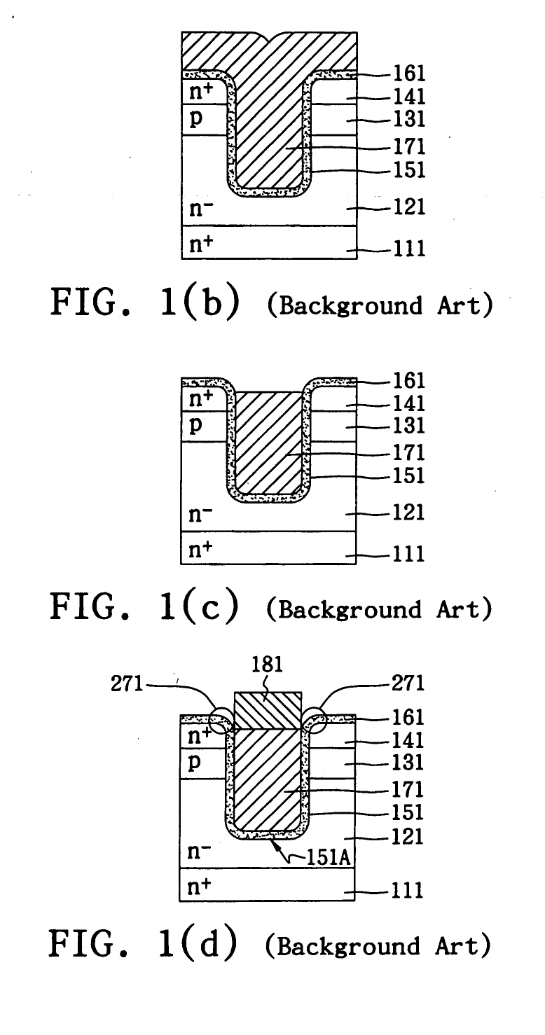

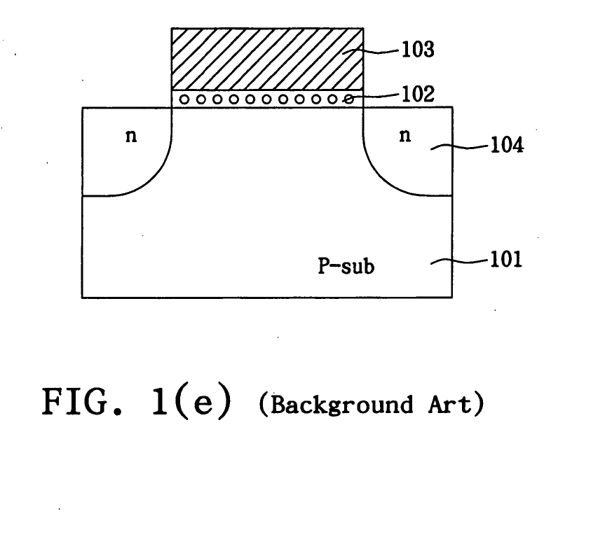

### DETAILED DESCRIPTION OF THE INVENTION

Embodiments of the present invention are now being described, with reference to the accompanying drawings.

A process for making a memory array having vertical transistors of NMOS type is exemplified as follows, with a view to illustrating the features of the present invention.

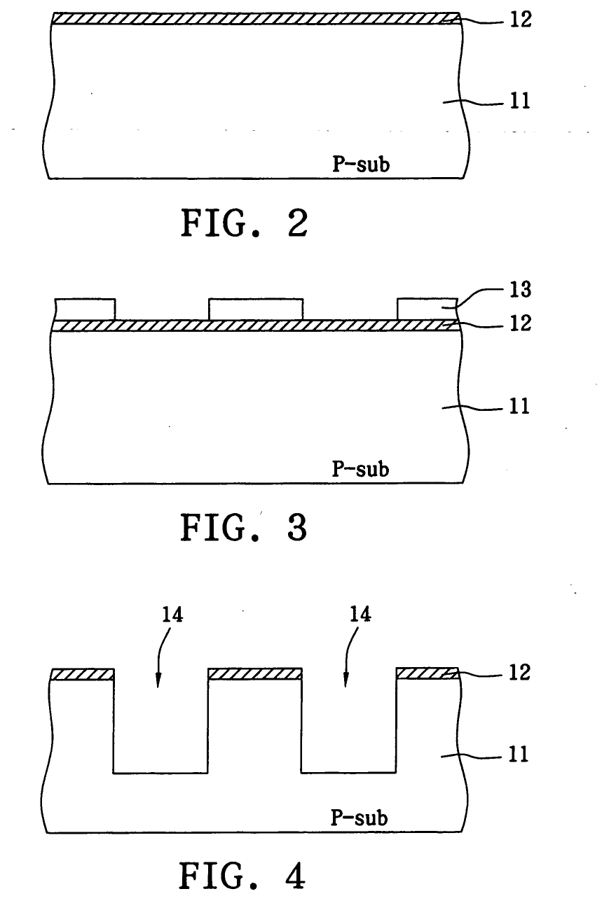

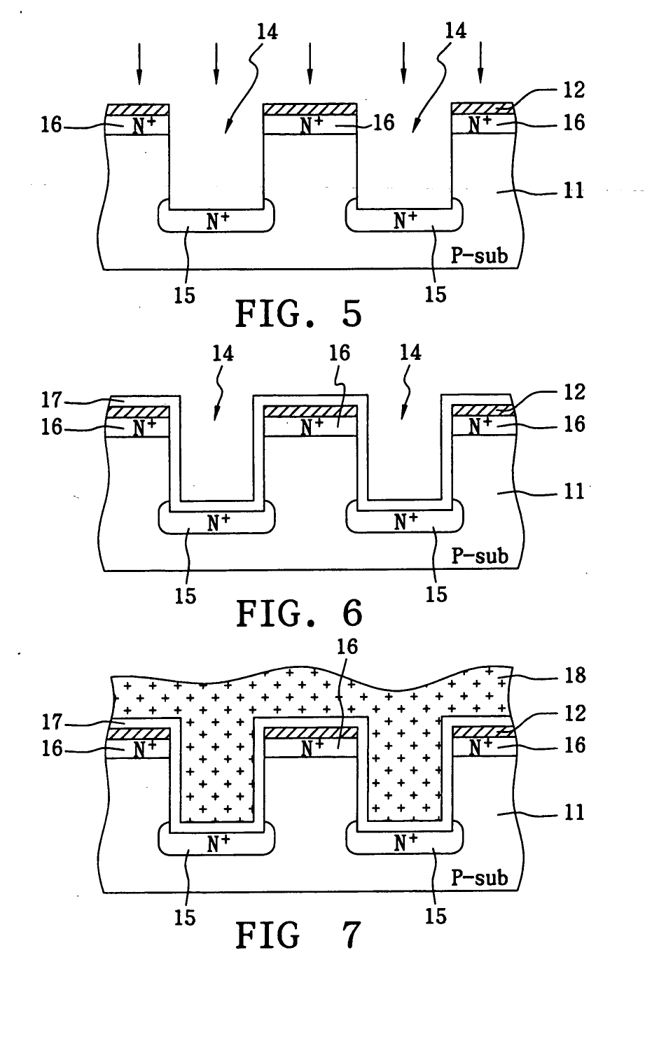

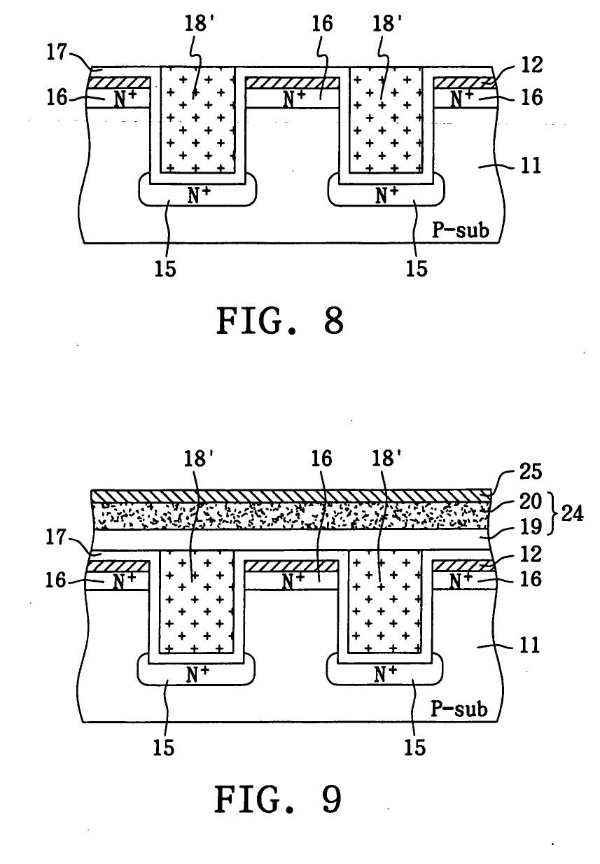

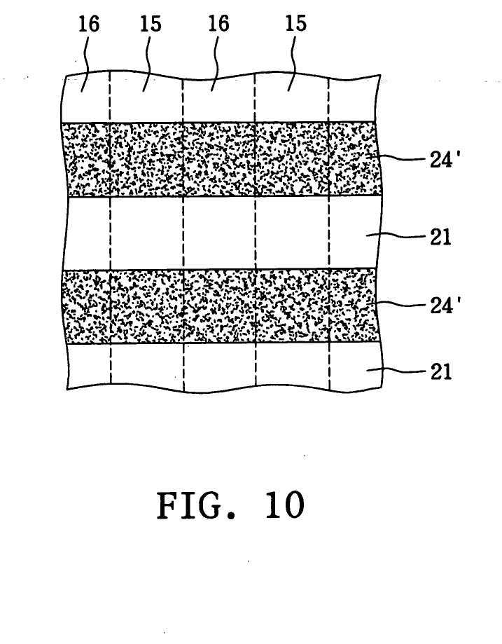

FIGS. 2 through 10 illustrate the memory structures at each step of the manufacturing process of a non-volatile memory array having vertical transistors in accordance with the present invention. In FIG. 2, a mask layer 12 is formed on a surface of a semiconductor substrate 11, e.g., a silicon substrate, where the mask layer 12 is typical of a thickness between 100-2000 angstroms, and can be composed of silicon nitride (SixNy), silicon oxide (SiOx), silicon oxynitride (SiOxNy) or multi-layer of the films. Then, a photoresist layer 13 is deposited on the surface of the mask layer 12, and is patterned to define multiple trenches as shown in FIG. 3. In FIG. 4, the mask layer 12 and the semiconductor substrate 11 are etched based on the patterned photoresist layer 13 to form multiple trenches 14, and the photoresist layer 13 is stripped afterward. Further, an annealing process at a temperature between 800-1100° C. may be employed to remove the damages caused by etching. In FIG. 5, N type dopants, such as arsenic ions are implanted into the semiconductor substrate 11 with an energy of approximately 80 Kev to form first and second doping regions 15 and 16 of N type at different heights of the semiconductor substrate 11 serving as source and drain, respectively. The first doping regions 15 are underneath the bottom of the trenches 14, and the second doping regions are beside the top of the trenches 14. In this embodiment, the first and second doping regions 15 and 16 act as bit lines for the memory array. Typically, the doping concentration of the regions 15 and 16 is between 5×10⁴ and 5×10⁵ atoms/cm³. Referring to FIG. 6, an oxide/nitride/oxide (ONO) layer 17 is formed along with the structure as shown in FIG. 4 as a gate dielectric for storing charges. The thicknesses of the oxide, nitride and oxide layers of the ONO layer 17 are 20-100 angstroms, 20-200 angstroms and 20-200 angstroms from bottom to top as usual, and are typically 50, 30 and 80 angstroms, or 25, 60, 60 angstroms, respectively, depending on device operating conditions. In other words, the ONO layer 17 having a total thickness between 60-500 angstroms is in wide use. In FIG. 7, a conducting layer, e.g., a polysilicon layer 18, is deposited by low pressure chemical vapor deposition (LPCVD) to fill up the trenches 14, and followed by a planarization process such as chemical mechanical polishing (CMP) to polish off the portion of the polysilicon layer 18 above the mask layer 12, thereby conducting plugs, i.e., polysilicon plugs 18′, are formed as shown in FIG. 8. In FIG. 9, another polysilicon layer 19, a tungsten silicide layer 20 and a silicon nitride 25 are sequentially deposited. The polysilicon layer 19 associated with the tungsten silicide layer 20, namely a polycide layer 24, of a thickness between 1000-4000 angstroms are commonly used, and 2000 angstroms is preferred in this embodiment. The silicon nitride layer 25 functions as an etch stop layer for the following planarization etching process. As shown in FIG. 10, depicting the top view of a portion of the memory array, a lithography process and an etching process are performed on the polycide layer 24 and polysilicon plugs 18′ to form separated polycide lines 24′ as word lines, which are approximately perpendicular to the first doping regions 15 (source bit lines) and the second doping regions 16 (drain bit lines), and holes dividing the polysilicon plugs 18′ into pieces. During the etching process, insulating layers such as the ONO layer 17 and the mask layer 12 on the top of the first and second doping regions 15, 16 serve as block layers to ensure that the doping regions 15, 16 maintain continuous. Then, an oxide layer 21 is deposited to fill up the holes and the spaces between the polycide lines 24′ by chemical vapor deposition (CVD) and is planarized thereafter by CMP for isolation.

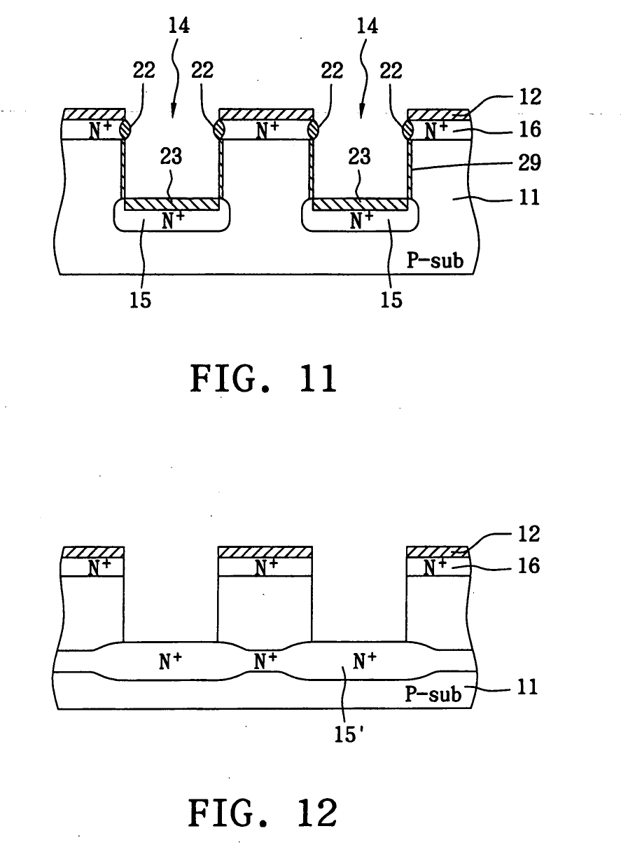

Moreover, prior to the ONO layer 17 formation, an oxidization step may be conducted to generate thicker insulation blocks 22 and 23 on the sidewalls of the second doping regions 16 and the top surface of first doping region 15 respectively, and edge insulation layers 29 are formed on the sidewalls of the trenches 14 as shown in FIG. 11. Because the doped silicon has a higher oxide growth rate, the insulation blocks 22 and 23 are thicker than the edge insulation layers 29 after oxidization. As a result, more superior isolation between the first and second doping regions 15, 16 from the polysilicon plugs 18′, i.e., gate electrode regions, can be achieved during device operating. Moreover, the edge insulation layers 29 formed on the sidewall of trenches 14 may be dipped away to make the pure ONO layer 17 as the gate dielectric, depending upon the thickness criteria of gate dielectric.

As shown in FIG. 12, a thermal process of 700-1100° C. may be further employed to diffuse the N dopants within the first doping regions 15 for forming a diffusion layer 15′ as a common source, thereby the number of contacts connecting to source can be tremendously diminished.

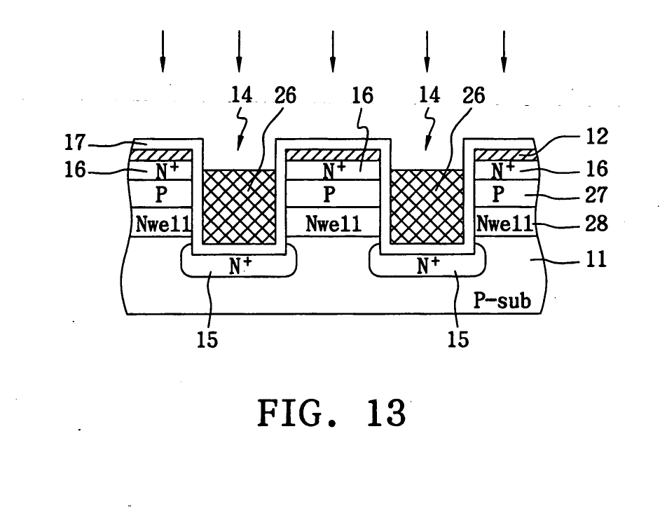

As shown in FIG. 13, a process for channel profile adjustment of the vertical transistors may be further employed prior to the formation of the polysilicon layer 18. First, photoresist 26 is deposited to fill the trenches 14, and followed by a hardening process to be a barrier for the following implantation. Next, N type dopants, e.g., phosphorus, and P type dopants, e.g., boron, are implanted into the substrate 11 at different depths to form third doping regions 27 of P type and fourth doping regions 28 of N type, wherein the third doping regions 27 are located higher than the fourth doping regions 28. The substrate 11 underneath the first doping regions 15 is not implanted with dopants owing to the shielding of the photoresist 26. Afterward, the photoresist 26 is removed.

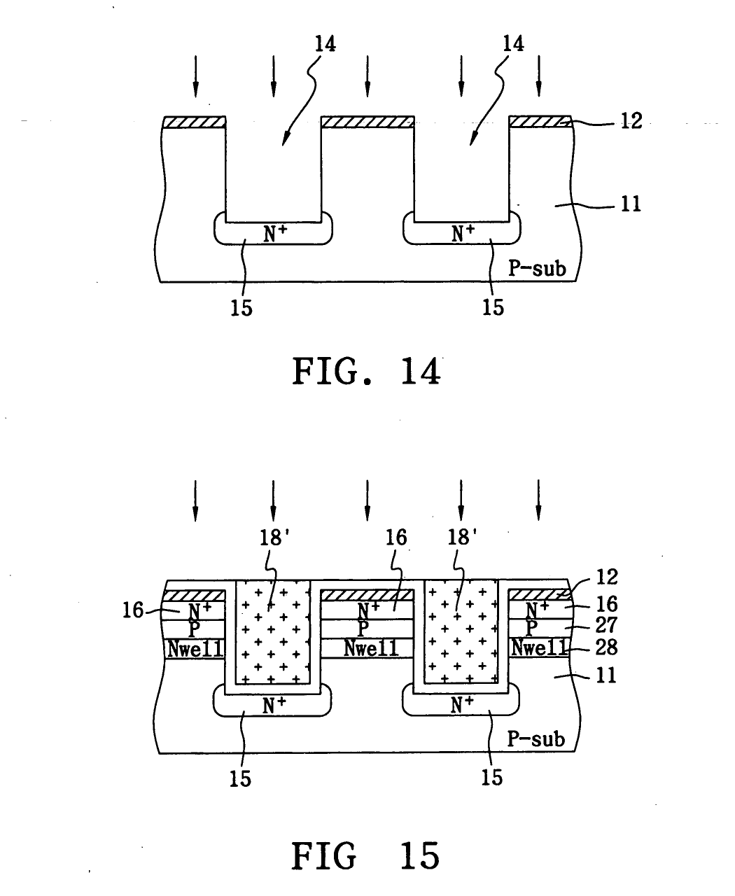

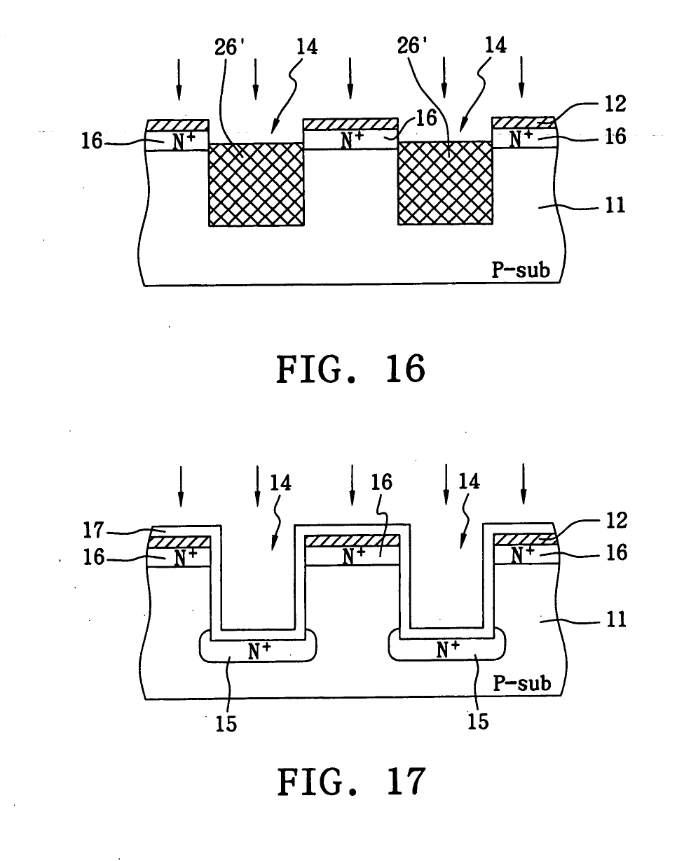

An alternative method for implanting dopants to form the first and the second doping regions 15, 16 are shown in FIGS. 14 and 15. First, a thicker nitride layer 12 and a lower implanting energy are used, for example, a silicon nitride layer 12 of 500-1500 angstroms and an implanting energy of 20-50 Kev, as to form the first doping regions 15 only.

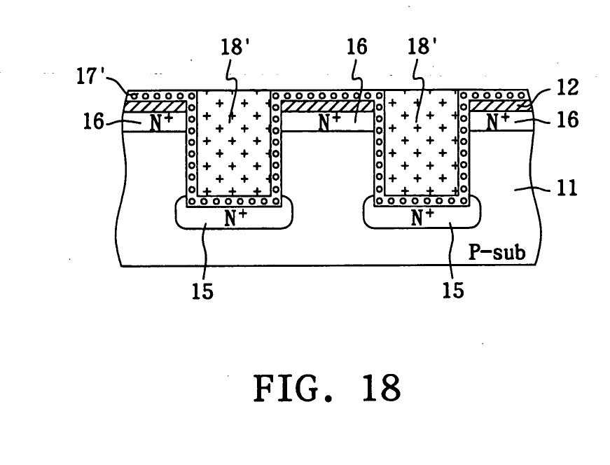

Then, proceeding with the similar process as shown in FIGS. 6-8 until the polysilicon plugs 18′ are formed, followed by another implanting step with a higher energy, e.g., 120-180 Kev or even higher energy, to form the second doping regions 16. In other words, the first and second doping regions 15, 16 are formed at different steps, the thicker mask layer 12 and the polysilicon plugs 18′ functions as the shields for the first and second implantations, respectively. As shown in FIG. 15, the third and fourth doping regions 27, 28 may further be formed likewise for channel profile adjustment of the vertical transistors. Another manufacturing process in different sequences to form the first and second doping regions 15, 16 are shown in FIGS. 16 and 17. In FIG. 16, blocking plugs, e.g., photoresist 26′, are filled in the trenches 14 as shields, and then implantation is conducted, so as to form the second doping regions 16 only. Then, another implantation is conducted after the photoresist 26′ is removed from the trenches 14 to form the first doping regions 15. In practice, the implantation to form the first doping regions 15 can be conducted before or after forming the ONO layer 17, for instance, FIG. 16 illustrates the case of implanting after the ONO layer 17 is deposited.

The silicon nanocrystals can also be employed to the non-volatile memory having vertical transistors as shown in FIG. 18. In comparison with FIG. 8, memory cells use a layer 17′ comprising nanocrystal particles instead of the ONO layer 17 as gate dielectric layer, with a view to further pushing the scaling limits. The silicon nanocrystal particles of the layer 17′ may be deposited at the required densities using optimized chemical vapor deposition (CVD) processes and be in the range of 5×10¹¹ to 5×10¹² cm⁻² as measured on active areas.

Besides the manufacturing method regarding NMOS type transistor as the above mentioned, the PMOS type transistor also can be implemented by doping boron ions without departing from the spirit of the present invention.

Table 1 exemplifies an operation method for the case of separated drain and source bit lines of N type in accordance with the present, in which the WL is the abbreviation of word line, and a hot electron programming and F-N channel erase is proposed for the array architecture.

TABLE 1

| | | De-Select | | | | | |
|---|---|---|---|---|---|---|---|
| Function | Select WL | WL | Drain | Source | Substrate | P_{well} | N_{well} |
| Read | 3-5 V | 0 V | 1 V | 0 V | 0 V | 0 V | 0 V |
| Program | 5-8 V | 0 V | 5 V | 0 V | 0 V | 0 V | 0 V |
| Erase | −15 V to −20 V | 0 V | 0 V | 0 V | 0 V | 0 V | 0 V |
| | −5 V to −12 V | 0 V | 5-8 V | 5-8 V | 0 V | 5-8 V | 5-8 V |
| | −5 V to −12 V | 0 V | 5-8 V | 5-8 V | 0 V | 0 V | 0 V |

Because the array structure is symmetrical, bias voltages applied to drain and source bit lines can be alternated. Thus, the charges can be stored on the ONO layer on both sides next to the drain and source regions.

Table 2 exemplifies an operation method for the case of common source bit lines of N type in accordance with the present, in which a hot electron programming, F-N channel programming and F-N channel erase can also be implemented as well.

TABLE 2

| | Select | De-Select | | | | | | | |
|---|---|---|---|---|---|---|---|---|---|
| Function | WL | WL | Drain | | Source | | Substrate | P_{well} | |
| Read | 3-5 V | 0 V | 1 | V | 0 | V | 0 V | 0 | V |
| Program | 5-8 V | 0 V | 5 | V | 0 | V | 0 V | 0 | V |
| | 5-12 V | 0 V | −5 to −8 | V | −5 to −8 | V | 0 V | −5 to −8 | V |
| Erase | −15 V to −20 V | 0 V | 0 | V | 0 | V | 0 V | 0 | V |
| | −5 V to −12 V | 0 V | 5-8 | V | 5-8 | V | 0 V | 5-8 | V |
| | −5 V to −12 V | 0 V | 5-8 | V | 0 | V | 0 V | 0 | V |

Accordingly, the non-volatile memory array made in accordance with the present invention can be well operated whereby a high degree integration of memory can be attained.

The above-described embodiments of the present invention are intended to be illustrative only. Numerous alternative embodiments may be devised by those skilled in the art without departing from the scope of the following claims.

1. A method for manufacturing a non-volatile memory array having vertical transistors, comprising the steps of:
providing a semiconductor substrate having trenches;
implanting dopants into the semiconductor substrate to form first doping regions and second doping regions at different heights, wherein the first doping regions are underneath the bottom of the trenches, and the second doping regions are beside the top of the trenches;
forming a gate dielectric layer on the semiconductor substrate, wherein the gate dielectric layer comprises at least one nitride film; and
forming conducting plugs in the trenches.

2. The method for manufacturing a non-volatile memory array having vertical transistors of claim 1, wherein the first and second doping regions are of a first conductive type selecting from one of N type and P type.

3. The method for manufacturing a non-volatile memory array having vertical transistors of claim 1, wherein the gate dielectric layer is an oxide/nitride/oxide layer.

4. The method for manufacturing a non-volatile memory array having vertical transistors of claim 1, further comprising an oxidization step to form edge insulation layers on sidewalls of the trenches and insulation blocks on the first and second doping regions, wherein the insulation blocks are thicker than the edge insulation layers.

5. The method for manufacturing a non-volatile memory array having vertical transistors of claim 1, further comprising a thermal process after the implanting step to diffuse the dopants within the first doping regions for connecting the first doping regions.

6. The method for manufacturing a non-volatile memory array having vertical transistors of claim 1, wherein the conducting plugs are polysilicon plugs.

7. The method for manufacturing a non-volatile memory array having vertical transistors of claim 6, wherein the polysilicon plugs are formed by the steps of:
depositing a polysilicon layer to fill up the trenches; and
planarizing the polysilicon layer.

8. The method for manufacturing a non-volatile memory array having vertical transistors of claim 1, further comprising the steps after the conducting plugs are formed:
depositing a polycide layer;
forming polycide lines and holes by masking and etching the polycide layer and the conducting plugs, wherein the polycide lines are substantially perpendicular to the first and second doping regions, and the holes divide the conducting plugs into pieces; and
forming an oxide layer in the holes and between polycide lines for isolation.

9. The method for manufacturing a non-volatile memory array having vertical transistors of claim 8, further comprising the step of forming an etch stop layer on the polycide layer after depositing the polycide layer.

10. The method for manufacturing a non-volatile memory array having vertical transistors of claim 8, further comprising the step of planarizing the oxide layer after the oxide layer is formed.

11. The method for manufacturing a non-volatile memory array having vertical transistors of claim 2, further comprising the step of implanting dopants of a second conductive type to form third doping regions beside the trenches for channel profile adjustment of the vertical transistors.

12. The method for manufacturing a non-volatile memory array having vertical transistors of claim 11, further comprising the step of implanting dopants of the first conductive type to form fourth doping regions beside the trenches, wherein the third doping regions are located higher than the fourth doping regions.

13. A method for manufacturing a non-volatile memory array having vertical transistors, comprising the steps of:
providing a semiconductor substrate having trenches;
implanting dopants of a first conductive type into the semiconductor substrate to form first doping regions underneath the bottom of the trenches;
forming a gate dielectric layer on the semiconductor substrate, wherein the gate dielectric layer comprises at least one nitride film; and
forming conducting plugs in the trenches; and
implanting dopants of the first conductive type into the semiconductor substrate to form second doping regions beside the top of the trenches.

14. The method for manufacturing a non-volatile memory array having vertical transistors of claim 13, further comprising a thermal process to diffuse the dopants within the first doping regions for connecting the first doping regions.

15. The method for manufacturing a non-volatile memory array having vertical transistors of claim 13, wherein the conducting plugs are polysilicon plugs.

16. A method for manufacturing a non-volatile memory array having vertical transistors, comprising the steps of:
providing a semiconductor substrate having trenches;
filling the trenches with blocking plugs;
implanting dopants of a first conductive type into the semiconductor substrate to form second doping regions beside the top of the trenches;
removing the blocking plugs;
implanting dopants of the first conductive type into the semiconductor substrate to form first doping regions underneath the bottom of the trenches;
forming a gate dielectric layer on the semiconductor substrate, wherein the gate dielectric layer comprises at least one nitride film; and
forming conducting plugs in the trenches.

17. The method for manufacturing a non-volatile memory array having vertical transistors of claim 16, wherein the blocking plugs are composed of photoresist.

18. A non-volatile memory array having vertical transistors, wherein at least one of the vertical transistors is formed in a trench of a semiconductor substrate and comprises:
a first doping region of a first conductive type being underneath the bottom of the trench;
a second doping region of the first conductive type being beside the top of the trench;
a gate dielectric layer formed on the first doping region, the second doping region and the sidewall of the trench, wherein the gate dielectric layer comprises at least one nitride film; and
a conducting plug formed in the trench.

19. The non-volatile memory array having vertical transistors of claim 18, wherein the semiconductor substrate is constituted of a silicon substrate and a mask layer.

20. The non-volatile memory array having vertical transistors of claim 19, wherein the mask layer is selected from the group of silicon nitride, silicon oxide, silicon oxynitride and multi-layer thereof.

21. The non-volatile memory array having vertical transistors of claim 19, wherein the mask layer is of a thickness between 100 to 2000 angstroms.

22. The non-volatile memory array having vertical transistors of claim 18, wherein the first and second doping regions functions as bit lines for the non-volatile memory array.

23. The non-volatile memory array having vertical transistors of claim 18, wherein the gate dielectric layer is an oxide/nitride/oxide layer.

24. The non-volatile memory array having vertical transistors of claim 23, wherein the oxide/nitride/oxide layer is of a thickness between 60-500 angstroms.

25. The non-volatile memory array having vertical transistors of claim 18, wherein the conducting plugs are polysilicon plugs.

26. The non-volatile memory array having vertical transistors of claim 18, wherein the at least one of the vertical transistors further comprises insulation blocks formed on the surfaces of the first and second doping regions.

27. The non-volatile memory array having vertical transistors of claim 26, wherein the at least one of the vertical transistors further comprises edge insulation layers formed on sidewalls of the trenches, and the insulation blocks are thicker than the edge insulation layers.

28. The non-volatile memory array having vertical transistors of claim 18, wherein the at least one of the vertical transistors further comprises a third region of a second conductive type beside the trench.

29. The non-volatile memory array having vertical transistors of claim 28, wherein the at least one of the vertical transistors further comprises a fourth doping region of the first conductive type beside the trench, and the third doping region is located higher than the fourth doping region.

30. The non-volatile memory array having vertical transistors of claim 18, wherein the first doping regions of the vertical transistors are connected as one of a common source and a common drain.

31. A non-volatile memory array having vertical transistors, wherein at least one of the vertical transistor is formed in a trench of a semiconductor substrate and comprises:
a first doping region of a first conductive type being underneath the bottom of the trench;
a second doping region of the first conductive type being beside the top of the trench;
a gate dielectric layer formed on the first doping region, the second doping region and the sidewall of the trench, wherein the gate dielectric layer comprises silicon nanocrystal particles; and
a conducting plug formed in the trench.

32. The non-volatile memory array having vertical transistors of claim 31, wherein the density of the silicon nanocrystal particles is in the range of 5×10¹¹ to 5×10¹² cm⁻².
